(19) United States
(12) Patent Application Publication
(10) Pub. No.: US 2008/0145534 A1
(43) Pub. Date: Jun. 19, 2008

(54) DEPOSITION APPARATUS WITH CAVITIES FOR A SUBSTRATE AND AN EVAPORATION SOURCE, AND DEPOSITION METHOD USING THE SAME

(76) Inventors: Joo-hyeon Lee, Gyeonggi-do (KR); Jin-koo Chung, Gyeonggi-do (KR); Chang-mo Park, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/930,855

(22) Filed: Oct. 31, 2007

(30) Foreign Application Priority Data
Dec. 19, 2006 (KR) 10-2006-0130410

(51) Int. Cl. C23C 14/24

(52) U.S. Cl. 427/255.6; 118/719; 118/727

(57) ABSTRACT

A deposition apparatus comprises a first cavity which comprises an evaporation source entrance and a gas discharge port; a second cavity operable to communicate with the first cavity through the evaporation source entrance; an opening/closing part which controllably opens and closes the evaporation source entrance; and a driver for moving the evaporation source between the first cavity and the second cavity through the evaporation source entrance.

### CROSS-REFERENCE TO RELATED APPLICATIONS

This application claims priority from Korean Patent Application No. 2006-0130410, filed on Dec. 19, 2006 in the Korean Intellectual Property Office, incorporated herein by reference.

### BACKGROUND OF THE INVENTION

1. Field of the Invention

The present invention relates to deposition of materials by evaporation. Some embodiments provide enhanced protection for the evaporation source. Some embodiments are suitable for deposition of organic materials in fabrication of organic light emitting diode displays (OLEDs).

2. Description of the Related Art

OLEDs are becoming a popular alternative to liquid crystal displays (LCD) and plasma displays because OLEDs have low power consumption, a wide viewing angle, and a high response speed. In addition, OLEDs can be light weight and small. Both passive matrix and active matrix OLEDs have been provided.

An OLED uses a hole injecting layer and a light emissive layer to form light emitting diodes that emit light to produce an image. The OLEDs can be divided into low molecular organic light emitting diode devices and polymer organic light emitting diode devices depending on the molecular weight of the hole injecting layer and/or the light emissive layer. Organic layers of low molecular weight can be formed by vacuum thermal evaporation onto the OLED's substrate. Some evaporation sources can however by corrupted by moisture and oxygen.

More particularly, in vacuum thermal evaporation, material is evaporated from an evaporation source heated in a vacuum. The evaporated material contacts the substrate at a low temperature to form a solid organic layer in a phase transition. In this process, the substrate and the evaporation source are held in a chamber under vacuum. When the chamber is opened for any reason such as maintenance, the evaporation source can be exposed to moisture or oxygen, and can be corrupted as a result.

### SUMMARY

This section summarizes some features of some embodiments of the invention. The invention is defined by the appended claims.

In some embodiments, a deposition apparatus is provided in which an evaporation source can be protected from exposure to moisture and oxygen.

In some embodiments, a deposition apparatus comprises a first body which comprises a first cavity having an evaporation source entrance and a gas discharge port; a second body which comprises a second cavity to communicate with the first cavity through the evaporation source entrance; an opening/closing part for controllably opening and closing the evaporation source entrance; and a driver for moving the evaporation source between the first cavity and the second cavity through the evaporation source entrance.

Some embodiments comprise a pump for pumping gas out of the first cavity through the gas discharge port. In some embodiments, the pump is also for pumping gas out of the second cavity at least when the second cavity is disconnected from the first cavity by the opening/closing part. Some embodiments comprise a gas supply for supplying gas to the second cavity. Some embodiments comprise a heater for heating the evaporation source.

Some embodiments include a deposition method comprising: providing a substrate in a first cavity; heating an evaporation source disposed in the first cavity to form an organic layer on the substrate while the first cavity and a second cavity are under vacuum; moving the evaporation source to the second cavity; and disconnecting the first cavity from the second cavity using an opening/closing part. In some embodiments, the method comprises supplying an inert gas to the second cavity when the first and second cavities have been disconnected. In some embodiments, the method comprises discharging gas from the second cavity when the first cavity and the second cavity have been disconnected. In some embodiments, the method comprises supplying an inert gas to the second cavity when the first and second cavities have been disconnected. In some embodiments, the first cavity is in communication with the second cavity during the formation of the organic layer.

Some embodiments include a deposition apparatus comprising: a first body having a first cavity for containing a substrate when material is evaporated onto the substrate from an evaporation source; a second body having a second cavity for receiving the evaporation source; a device for controllably blocking communication between the first and second cavities to protect the evaporation source when the material is not evaporated onto the substrate; and a pumping system for providing vacuum in the first and second cavities when the material is evaporated onto the substrate, the pumping system being operable to provide vacuum in the second cavity independently of gas pressure in the first cavity when communication between the first and second cavities is blocked. Some embodiments comprise a mechanism for moving the evaporation source at least partially out of the second cavity into the first cavity to perform evaporation from the evaporation source onto the substrate.

Other embodiments and variations are within the scope of the invention, as defined by the appended claims.

### BRIEF DESCRIPTION OF THE DRAWINGS

The above and/or other aspects and advantages of the present invention will become apparent and more readily appreciated from the following description of some embodiments, taken in conjunction with the accompanying drawings in which:

FIGS. 1 and 2 illustrate a deposition apparatus according to a first exemplary embodiment of the present invention;

FIGS. 3A to 3D illustrate a deposition method using the deposition apparatus according to the first exemplary embodiment;

FIGS. 4 and 5 illustrate a deposition apparatus according to a second exemplary embodiment of the present invention; and

FIG. 6 illustrates a deposition method using the deposition apparatus according to the second exemplary embodiment.

### DESCRIPTION OF SOME EMBODIMENTS

Some embodiments of the present invention will now be described with reference to the accompanying drawings. Like numerals refer to like elements in the drawings and repetitive description will be avoided as appropriate.

### First Exemplary Embodiment

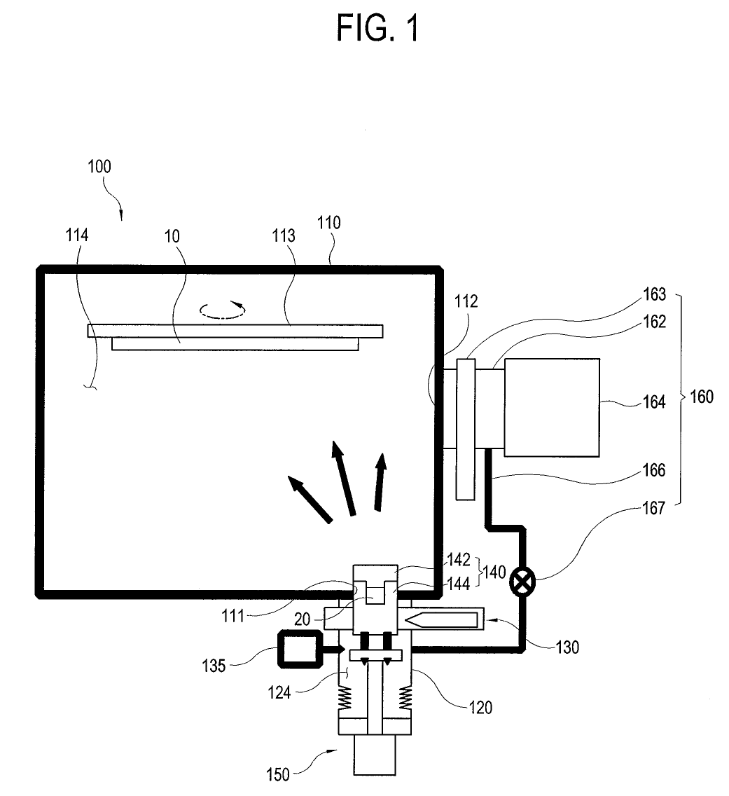

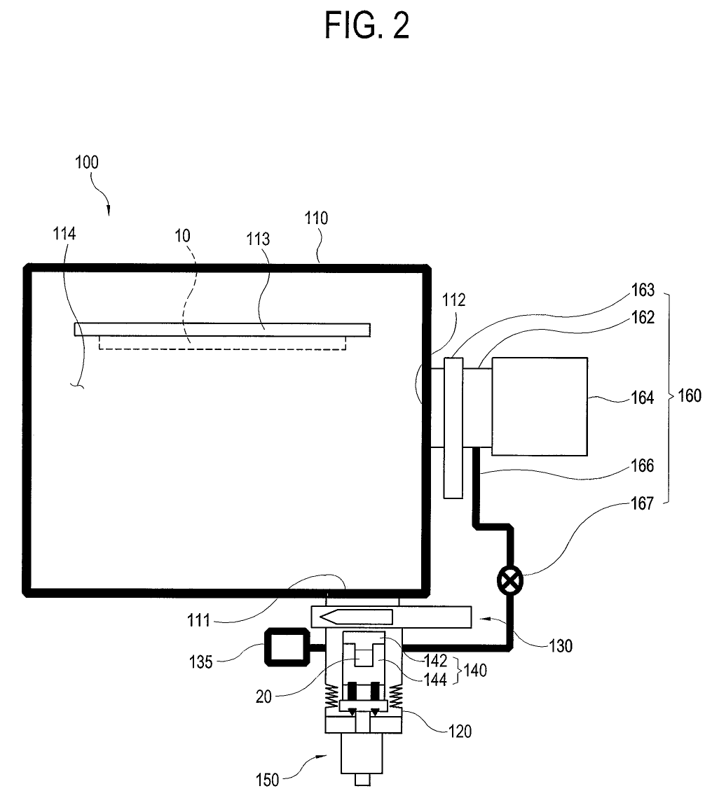

FIGS. 1 and 2 illustrate a deposition apparatus according to the first exemplary embodiment. The deposition apparatus 100 includes a deposition chamber 110, a cylinder body 120, an opening/closing valve (opening/closing part) 130, a cylinder 140 and a driver 150.

A first cavity 114 is provided in the deposition chamber 110 to hold a substrate 10 therein. The deposition chamber 110 includes a gas discharge port 112 through which gas is pumped out of the first cavity 114 to the exterior, and an evaporation source entrance 111 to admit the cylinder 140 with an evaporation source 20 in the cylinder.

The cylinder body 120 has a second cavity 124 which communicates with the first cavity 114 through the evaporation source entrance 111. The opening/closing valve 130 controllably opens and closes the evaporation source entrance 111.

The cylinder 140 reciprocates between the first and second cavities 114 and 124. The cylinder 140 includes a holding part 142 to hold the evaporation source 20 therein, and a heater 144 adjacent to the holding part 142. The heater 144 heats the evaporation source 20 held in the holding part 142. Material of the evaporation source 20 held in the holding part 142 is vaporized by the heat from the heater 144 and is deposited on the substrate 10.

The driver 150 operates to move the cylinder 140 between the first and second cavities 114 and 124. In some variations, the driver 150 includes ascenting/descenting shafts at the bottom of the cylinder 140, a rack at one side thereof, a pinion to be engaged with the rack, and a driving motor to supply power to the pinion. Alternatively, the driver 150 can drive the cylinder by fluid or vapor pressure to cause the cylinder 140 to reciprocate.

The cylinder 140 reciprocates through the evaporation source entrance 111 of the deposition chamber 110 so that the evaporation source 20 moves in and out of the first cavity 114 of the deposition chamber 110. A pump 160 may pump gas out of the first cavity 114 through the gas discharge port 112. The pump 160 includes a first gas discharging pipe 162 and a vacuum pump 164.

The first gas discharging pipe 162 has a first end connected with the gas discharge port 112 and a second end connected with the vacuum pump 164. Thus, the vacuum pump 164 can pump gas out of the first cavity 114 of the deposition chamber 110 through the first gas discharging pipe 162. The first gas discharging pipe 162 includes a first shut-down valve 163 to block the pipe to disconnect the deposition chamber 110 from the vacuum pump 164.

The pump 160 further includes a second gas discharging pipe 166 which connects the vacuum pump 164 to the cylinder body 120 to pump gas out of the second cavity 124.

The second gas discharging pipe 166 has a first end connected with the cylinder body 120 and a second end connected with the vacuum pump 164.

A second shut-down valve 167 is provided in the second gas discharging pipe 166 to block the pipe to disconnect the cylinder body 120 from the vacuum pump 164.

As shown in FIG. 1, the evaporation source 20 is heated to deposit a thin film on the substrate 10 when the cylinder 140 has moved from the second cavity 124 of the cylinder body 120 to the first cavity 114 of the deposition chamber 110.

If the evaporation source 20 is reactive to moisture or oxygen, the evaporation source 20 may deteriorate if exposed to moisture or oxygen. Of note, the material evaporated from the evaporation source 20 is in the gaseous state, and hence is especially reactive. Therefore, the deposition chamber 110 is preferably kept under vacuum during deposition.

To provide the vacuum, the vacuum pump 164 pumps gas out of the first cavity 114 to the exterior through the first gas discharging pipe 162 during the evaporation from the evaporation source 20. The first shut-down valve 163 is open at this time.

As described above, the thin film is formed on the substrate 10 when the cylinder 140 is in the first cavity 114 of the deposition chamber 110. The first and second cavities 114 and 124 are connected with each other through the opening/closing valve 130 and thus are under the same environment. If the deposition chamber 110 has to be opened for some reason, e.g. to unload the substrate 10 or in case of malfunction, the evaporation source 20 could be exposed to the external environment, which may contain moisture or oxygen that can damage the evaporation source.

As shown in FIG. 2, to protect the evaporation source 20 when the deposition chamber 110 is opened, the cylinder 140 is withdrawn from the deposition chamber 110 into the second cavity 124 in the cylinder body 120. Then the vacuum pump 164 is operated to preferably pump gas out of the second cavity 124 to the exterior through the second gas discharging pipe 166. The second shut-down valve 167 is opened to accomplish such operation.

A vacuum gauge 135 is mounted in the cylinder body 120 adjacent to the opening/closing valve 130 to measure the degree of vacuum in the second cavity 124. As the vacuum gauge 135 may be damaged by the heater 144 when the evaporation source 20 is being heated, a cooler may be provided adjacent to the vacuum gauge 135.

In the first exemplary embodiment, the vacuum pump 164 is the only pump that pumps gas out of the deposition chamber 110 and the cylinder body 120 to the exterior through the first and second gas discharging pipes 162 and 166, and possibly through other paths. Alternatively, different vacuum pumps can be provided for the first and second gas discharging pipes 162 and 166 respectively.

In the deposition apparatus 100 according to the first embodiment, the cylinder 140 can move between the first and second cavities 114 and 124 due to operation of the driver 150. Therefore, the evaporation source 20 can be moved from the deposition chamber 110 into the cylinder body 120 together with the cylinder 140 before the deposition chamber 110 is opened.

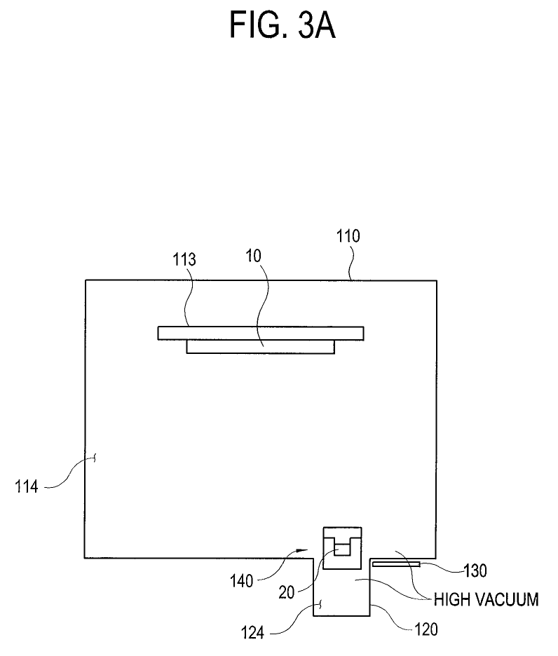

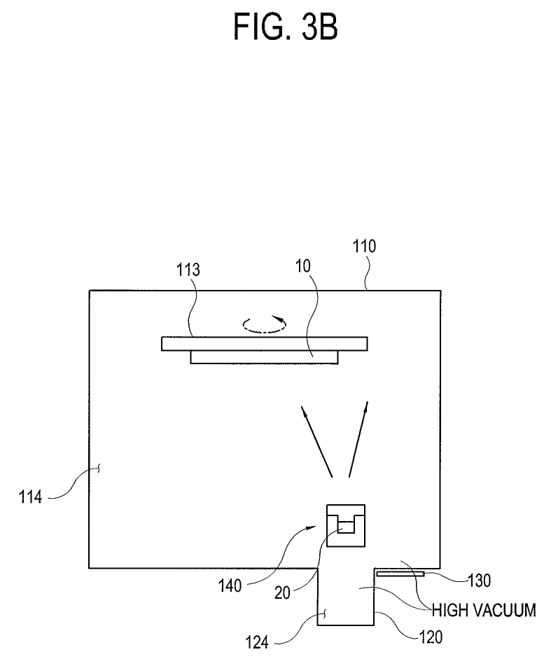

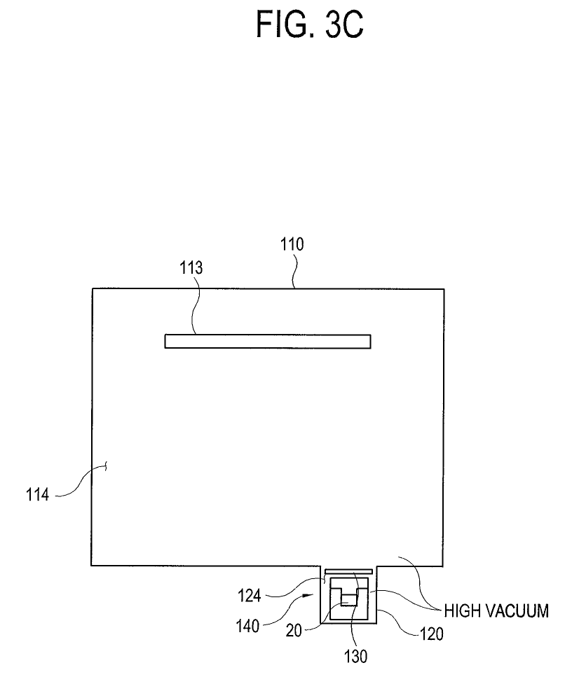

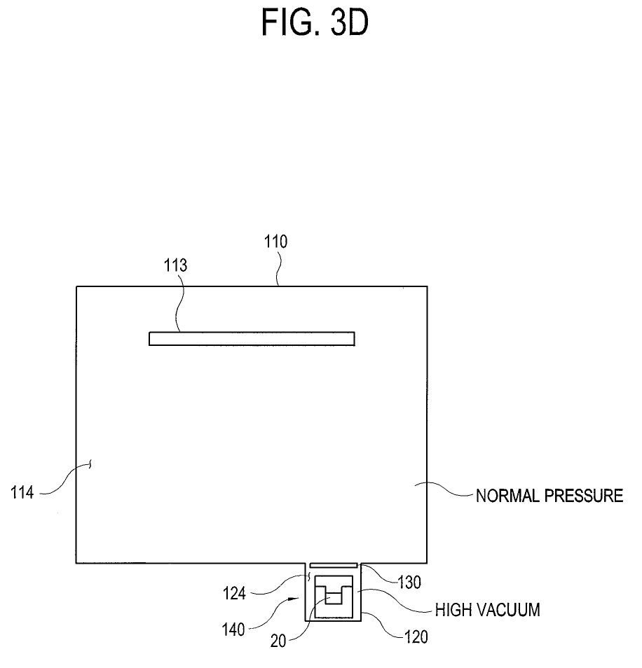

Now operation of the deposition apparatus 100 according to some embodiments of the present invention will be described with reference to FIGS. 3A to 3D. As shown in FIG. 3A, a rotating holder 113 is provided in the deposition chamber 110 in the first cavity 114. The substrate 10 is held by the rotating holder 113.

The first and second cavities 114 and 124 communicate with each other through the opening/closing valve 130 and are under the same vacuum.

As shown in FIG. 3B, the rotating holder 113 rotates during deposition to facilitate uniform deposition of evaporated material from the evaporation source 20 onto the substrate 10. The first and second cavities 114 and 124 are maintained under the same degree of vacuum during the deposition process. A shadow mask or an open mask may be provided in front of the substrate 10.

As shown in FIG. 3C, if the deposition chamber 110 needs to be opened, the cylinder 140 containing the evaporation source 20 is moved into the cylinder body 120. Then the first and second cavities 114 and 124 are disconnected from each other by the opening/closing valve 130.

Then the first cavity 114 can be brought to atmospheric pressure (“NORMAL PRESSURE” in FIG. 3D), or at least the vacuum can be lowered in the first cavity 114, to address any malfunction or other problems related to the deposition chamber 110. Meanwhile, the second cavity 124 can be maintained in a high vacuum state with the evaporation source 20 being protected from moisture or oxygen. The degree of vacuum in second cavity 124 may be increased or lowered or kept unchanged by the vacuum pump 164 as needed.

When the deposition chamber 110 has been serviced to address any malfunction or other issues (e.g. maintenance issues), the first and second cavities 114 and 124 are provided with high vacuum. Then the substrate 10 and the evaporation source 20 are moved back into the first cavity 114 of the deposition chamber 110.

### Second Exemplary Embodiment

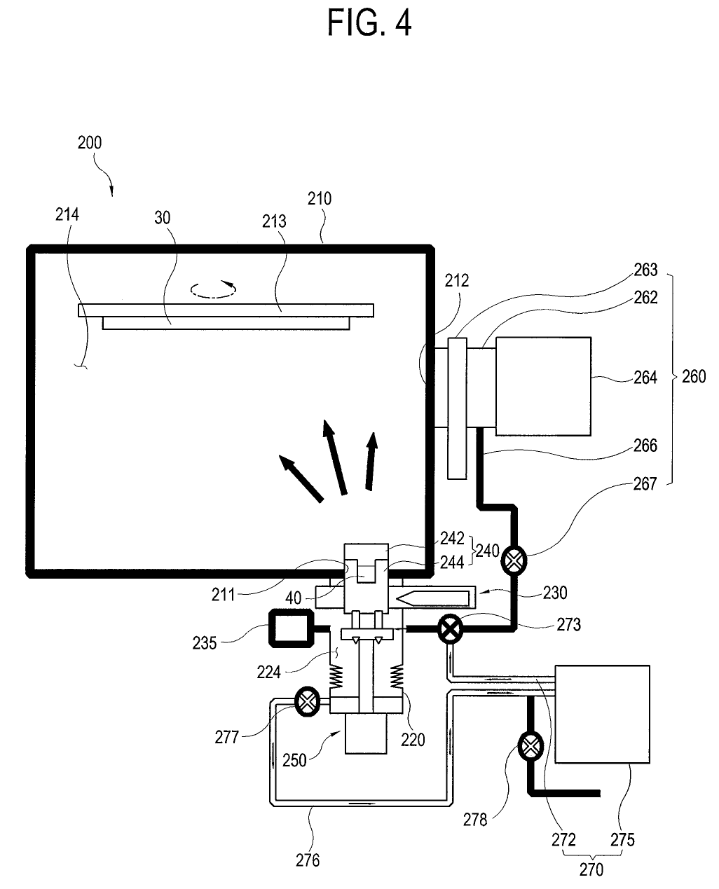

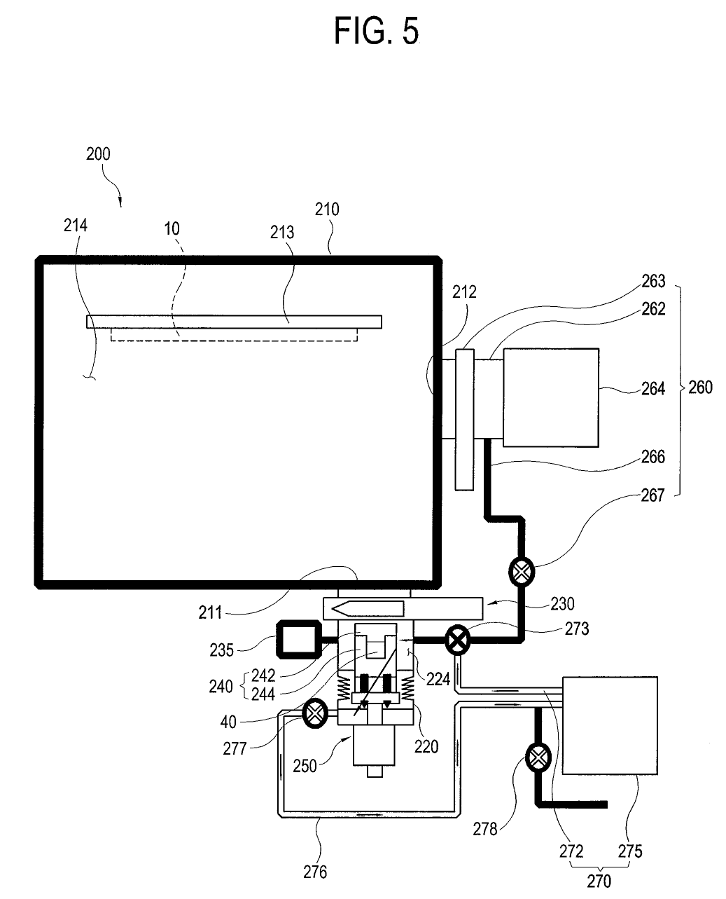

FIGS. 4 and 5 illustrate a deposition apparatus according to the second exemplary embodiment of the present invention.

As shown therein, the deposition apparatus 200 includes a deposition chamber 210, a cylinder body 220, an opening/closing valve 230, a cylinder 240 and a driver 250.

A first cavity 214 is provided in the deposition chamber 210 to hold a substrate 30 therein. The deposition chamber 210 includes a gas discharge port 212 through which gas is pumped out of the first cavity 214 to the exterior, and a evaporation source entrance 211 to admit the cylinder 240 with an evaporation source 40 from which material is evaporated onto the substrate 30 to form a thin film on the substrate.

The cylinder body 220 has a second cavity 224 which communicates with the first cavity 214 through the evaporation source entrance 211. The opening/closing valve 230 controllably opens and closes the evaporation source entrance 211.

The cylinder 240 reciprocates between the first and second cavities 214 and 224. The cylinder 240 includes a holding part 242 to hold the evaporation source 40 therein, and a heater 244 adjacent to the holding part 242 to heat the evaporation source 40 held in the holding part 242. Material of the evaporation source 40 held in the holding part 242 is vaporized by the heat from the heater 244.

The driver 250 moves the cylinder 240 between the first and second cavities 214 and 224. In some variations, the driver 250 includes ascenting/descenting shafts provided at the bottom of the cylinder 240, a rack at one side thereof, a pinion to be engaged with the rack, and a driving motor to supply power to the pinion. Alternatively, the driver 250 may drive the cylinder by fluid or vapor pressure to cause the cylinder 240 to reciprocate.

The cylinder 240 reciprocates through the evaporation source entrance 211 of the deposition chamber 210 so that the evaporation source 40 moves in or out of the first cavity 214 of the deposition chamber 210.

A pump 260 may pump gas out of the first cavity 214 through the gas discharge port 212 of the deposition chamber 210. The pump 260 includes a first gas discharging pipe 262 and a vacuum pump 264.

The first gas discharging pipe 262 has a first end connected with the gas discharge port 212 and a second end connected with the vacuum pump 264. Thus, the vacuum pump 264 pumps gas out of the first cavity 214 of the deposition chamber 210 through the first gas discharging pipe 262. The first gas discharging pipe 262 may include a first shut-down valve 263 to block the pipe to disconnect the deposition chamber 210 from the vacuum pump 264.

The pump 260 further includes a second gas discharging pipe 266 which connects the vacuum pump 264 to the cylinder body 220 to pump gas out of the second cavity 224 of the cylinder body 220.

The second gas discharging pipe 266 has a first end connected with the cylinder body 220 and a second end connected with the vacuum pump 264 to pump gas out of the second cavity 224.

A second shut-down valve 267 is provided in the second gas discharging pipe 266 to block the pipe to disconnect the cylinder body 220 from the vacuum pump 264.

As shown in FIG. 4, the evaporation source 40 is heated to deposit a thin film on the substrate 30 when the cylinder 240 has moved from the second cavity 224 of the cylinder body 220 to the first cavity 214 of the deposition chamber 210.

If the evaporation source 40 is reactive to moisture or oxygen, the evaporation source 40 may deteriorate if exposed to moisture or oxygen. Of note, the material evaporated from the evaporation source 40 is in the gaseous state, and hence is especially reactive. Therefore, the deposition chamber 210 is preferably kept under vacuum during deposition.

To provide the vacuum, the vacuum pump 264 pumps gas out of the first cavity 214 to the exterior through the first gas discharging pipe 262 during the evaporation from the evaporation source 20. The first shut-down valve 263 is open at this time.

As described above, the thin film is formed on the substrate 30 when the cylinder 240 is in the first cavity 214 of the deposition chamber 210. If the deposition chamber 210 has to be opened for some reason, e.g. to unload the substrate 30 or in case of malfunction, the evaporation source 40 could be exposed to the external environment, which may contain moisture or oxygen that can damage the evaporation source.

As shown in FIG. 5, to protect the evaporation source 40 when the deposition chamber 210 is opened, the cylinder 240 is withdrawn from the deposition chamber 110 into the second cavity 224. Then, the vacuum pump 264 preferably pumps gas out of the second cavity 224 to the exterior through the second gas discharging pipe 266. The second shut-down valve 267 is open to accomplish such operation.

In the second exemplary embodiment, the vacuum pump 264 pumps out both the deposition chamber 210 and the cylinder body 220 through the respective first and second gas discharging pipes 262 and 266, but this is not limiting. In some embodiments, different vacuum pumps are provided for the first and second gas discharging pipes 262 and 266 respectively.

A vacuum gauge 235 is mounted in the cylinder body 220 adjacent to the opening/closing valve 230 to sense the degree of vacuum in the second cavity 224. As the vacuum gauge 235 may be damaged by the heater 244 when the evaporation source 40 is being heated, a cooler may be provided adjacent to the vacuum gauge 235.

In the second exemplary embodiment, when the cylinder 240 is disposed in the cylinder body 220, the cylinder body 220 can be pumped down to vacuum by the vacuum pump 264 as needed to protect the evaporation source 40. Additional protection is provided by a gas supply 270 operable to supply inert gas to the cylinder body 220.

The gas supply 270 includes an injection pipe 272 having a first end connected with the cylinder body 220 and having a second end connected to a gas supply source 275. The injection pipe 272 can conduct the inert gas from the gas supply source 275 to the cylinder body 220.

A third shut-down valve 273 is mounted in the injection pipe 272 to either allow or block the inert gas flow from the gas supply source 275 to the cylinder body 220. When the third shut-down valve 273 is open, the inert gas can be supplied to the cylinder body 220. The inert gas displaces the gas in the cylinder body 220, forcing such gas to the outside through a gas discharging pipe 276. First and second opening valves 277 and 278 are open to allow gas discharge from the cylinder body 220 through the gas discharging pipe 276.

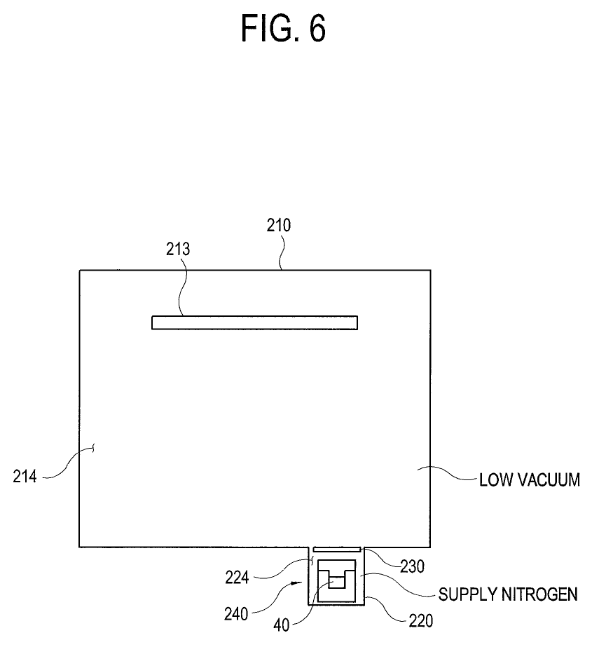

Operation of the deposition apparatus will now be described. The apparatus according to the second exemplary embodiment can be operated in the same manner as the first exemplary embodiment as shown in FIGS. 3A to 3D, except that when the first cavity 214 is at atmospheric pressure or in a low vacuum state, the gas supply 270 may supply inert gas such as nitrogen to the second cavity 224 as shown in FIG. 6.

As described above, some embodiments of the present invention provide a deposition apparatus in which an evaporation source is moved in and out of a chamber in a simple manner. Also, the evaporation source is protected if the deposition chamber is open to outside atmosphere.

Although a few exemplary embodiments of the present invention have been shown and described, it will be appreciated by those skilled in the art that changes may be made in these exemplary embodiments without departing from the principles of the invention, the scope of which is defined by the appended claims and their equivalents.

What is claimed is:

1. A deposition apparatus, comprising:
a first body which comprises a first cavity having an evaporation source entrance and a gas discharge port;
a second body which comprises a second cavity to communicate with the first cavity through the evaporation source entrance;
an opening/closing part for controllably opening and closing the evaporation source entrance; and
a driver for moving the evaporation source between the first cavity and the second cavity through the evaporation source entrance.

2. The deposition apparatus according to claim 1, further comprising a pump for pumping gas out of the first cavity through the gas discharge port.

3. The deposition apparatus according to claim 2, wherein the pump is also for pumping gas out of the second cavity at least when the second cavity is disconnected from the first cavity by the opening/closing part.

4. The deposition apparatus according to claim 1, further comprising a gas supply for supplying gas to the second cavity.

5. The deposition apparatus according to claim 1 further comprising a heater for heating the evaporation source.

6. A deposition method using the deposition apparatus according to claim 1, comprising:
providing a substrate in the first cavity;
heating the evaporation source disposed in the first cavity to form an organic layer on the substrate while the first cavity and the second cavity are under vacuum;
moving the evaporation source to the second cavity; and
disconnecting the first cavity from the second cavity using the opening/closing part.

7. The method according to claim 6, further comprising supplying an inert gas to the second cavity when the first and second cavities have been disconnected.

8. The method according to claim 6, further comprising discharging gas from the second cavity when the first cavity and the second cavity have been disconnected.

9. The method according to claim 8, further comprising supplying an inert gas to the second cavity when the first and second cavities have been disconnected.

10. The method according to claim 6, wherein the first cavity is in communication with the second cavity during the formation of the organic layer.

11. A deposition apparatus comprising:
a first body having a first cavity for containing a substrate when material is evaporated onto the substrate from an evaporation source;
a second body having a second cavity for receiving the evaporation source;
a device for controllably blocking communication between the first and second cavities to protect the evaporation source when the material is not evaporated onto the substrate; and
a pumping system for providing vacuum in the first and second cavities when the material is evaporated onto the substrate, the pumping system being operable to provide vacuum in the second cavity independently of gas pressure in the first cavity when communication between the first and second cavities is blocked.

12. The apparatus according to claim 11 further comprising a mechanism for moving the evaporation source at least partially out of the second cavity into the first cavity to perform evaporation from the evaporation source onto the substrate.
